(19) United States
(12) Patent Application Publication
(10) Pub. No.: US 2015/0255638 A1
(43) Pub. Date: Sep. 10, 2015

(54) method of modifying an n-type silicon substrate

(71) Applicant: OPTITUNE OY, Oulu (FI)

(72) Inventors: Ari Kärkkäinen, Singapore (SG); Milja Hannu-Kuure, Oulu (FI); Henna Järvitalo, Oulu (FI); Paul Williams, Singapore (SG); Jarkko Leivo, Oulu (FI); Admir Hadzic, Oulu (FI); Jianhui Wang, Singapore (SG)

(21) Appl. No.: 14/430,558

(22) PCT Filed: Sep. 24, 2013
(86) PCT No.: PCT/FI2013/050926

§ 371 Date: Mar. 24, 2015

Related U.S. Application Data
(60) Provisional application No. 61/704,764, filed on Sep. 24, 2012.

(30) Foreign Application Priority Data
Sep. 24, 2012 (FI) 20125988

(51) Int. Cl. H01L 31/0216; H01L 31/028; H01L 21/02; H01L 31/054; H01L 31/18

(52) U.S. Cl. CPC H01L 31/02167; H01L 31/0547; H01L 31/18; H01L 21/02282; H01L 21/02126; H01L 21/02274; H01L 21/0228; H01L 31/028

(57) ABSTRACT

A method of modifying a silicon substrate which is intended for use in a photovoltaic device, comprising the steps of providing an n-type silicon substrate having a bulk and exhibiting a front surface and a rear surface; and forming by liquid phase application dielectric layers on said front and rear surfaces. The dielectric layer formed at the rear surface is capable of acting as a reflector to enhance reflection of light into the bulk of the silicon substrate, and the dielectric layer formed at the front comprises oxygen, hydrogen and at least one metal or semimetal and is capable of releasing hydrogen into the bulk as well as onto the surfaces of the silicon substrate in order to provide hydrogenation and passivation. The present invention provides a low cost method of improving the electrical or optical performance, or both, of photovoltaic devices: an increase in the efficiency of the current extraction and reduction of recombination occur within the device.

### TECHNICAL FIELD

This invention relates to modified silicon substrates. In particular, the present invention concerns a method of modifying n-type crystalline silicon solar cells suitable for photovoltaic devices. Described herein are also hybrid and inorganic chemicals and polymers for use in the modification method, applied in combination with surface treatments, as well as processes and methods of delivery of the chemicals and activation thereof.

### BACKGROUND ART

Crystalline solar cells have been dominantly made from p-type of silicon materials. However, to manufacture high efficiency solar cells, n-type silicon has greater potential due to its better tolerance to impurities, e.g. Fe, which leads to higher minority carrier diffusion lengths compared to p-type c-Si substrates with a similar impurity concentration. In addition, n-type materials do not suffer from light-induced degradation (LID) by boron-oxygen pairs, which is believed to cause the light induced degradation (LID) of p-type c-Si solar cells.

To further improve the performance of solar cells, manufacturers have been using additional thin layers on the front or back surfaces, or on both, in order to reduce or even to eliminate surface recombination. Such additional layers should have excellent passivating characteristics to the device structure by removing the traps from the device. The passivating layers reduce the carrier recombination at silicon surfaces and therefore the introduction of such layers results in a higher open-circuit voltage, which becomes increasingly important for high-performing solar cells. If applied on the front surface of the solar cells, the passivating layers act as anti-reflective coatings (ARC) as well.

On the other hand, when the coating layers are applied at the backside of solar cells, the optical parameters of this additional layer could be designed in such a way to improve the internal reflectivity in the device to enhance the light absorption by the device, and as a consequence, increase the efficiency of the device.

Traditional surface passivation materials include SiOx, SiNx and etc which are usually prepared using vacuum techniques, such as, thermal oxidation, plasma-enhanced chemical vapour deposition (PECVD), or sputtering.

Recently, AlOx has drawn more attention both academically and in industry. It has been demonstrated that amorphous AlOx films prepared by Atomic Layer Deposition (ALD) or Plasma Enhanced Chemical Vapor Depostion (PECVD) yield an excellent level of surface passivation on c-Si. However, due to the complexity of the PECVD and other processes, and the relatively high cost of the manufacturing tools and consumable chemicals and gases (e.g. Trimethylaluminium or TMA), it is of great importance to develop alternative solutions to form dielectric coatings for silicon wafer solar cells.

Liquid phase deposition is such a competitive approach which is of comparable passivation quality, cost-effective, and environmental friendly. With that, coatings prepared under atmospheric conditions can be achieved whereby it is possible to eliminate those complex and expensive manufacturing tools.

### SUMMARY OF THE INVENTION

The invention is based on the concept of applying by liquid deposition a chemical composition onto either one or both of the front and rear surfaces of a photovoltaic (in the following also abbreviated “PV”) device to form a thin dielectric layer, typically having a thickness ranging from 5 to 250 nm.

The formed layer at the front gives rise to properties of hydrogenation, passivation and anti-reflection, to reduce surface and bulk recombination, and improve light absorption.

The layer formed at the back acts as a reflector to enhance the reflection of light, especially in the NIR range, into bulk silicon.

In addition, upon treating the chemical composition it is activated and introduces hydrogen into the bulk as well as onto the surface of the PV device to improve the passivation.

More specifically, the present method of modifying a silicon substrate which is intended for use in a photovoltaic device, comprises the steps of
providing an n-type silicon solar cell substrate having a bulk and exhibiting a front surface and a rear surface; and
forming by liquid phase application at least one dielectric layer on either or both of said front and rear surfaces.

The dielectric layer formed at the rear surface is capable of acting as a reflector to enhance reflection of light into the bulk of the silicon substrate, and the dielectric layer formed at the front comprises oxygen, hydrogen and at least one metal or semimetal and is capable of releasing hydrogen into the bulk as well as onto the surfaces of the silicon substrate in order to provide hydrogenation and passivation.

### ADVANTAGEOUS EFFECTS OF INVENTION

Considerable advantages are obtained by the invention. The present invention provides a low cost method of improving the electrical or optical performance, or both, of photovoltaic devices: an increase in the efficiency of the current extraction and reduction of recombination occur within the device. This results in greater power output from the device.

The present procedure offers an alternative to the existing ALD and/or PECVD method using TMA, SiH₄ and other gases, enabling the PV manufacturers to apply chemicals rather than work with hazardous gases to produce a series of layers that provide passivation as well as light utilization. The present technology makes it possible, in the case of thick film solar cell production, to have the whole manufacturing sequence performed using chemicals applied under atmospheric conditions and without the use of any hazardous gas or PECVD with the additional benefit of cost reduction and better process control and equipment sustainability.

Thus, in short, the modification of the surface(s) result in higher photo-generated minority carrier lifetime, improved internal reflection at Near Infrared (NIR) range, and subsequent efficiency of the solar device.

### BRIEF DESCRIPTION OF DRAWINGS

FIG. 1 is a schematic representation of a process flow for an n-type crystalline silicon solar cell fabrication with deposition of the chemical onto the front and back surfaces of the PV device with Al₂O₃ deposited by PECVD, ALD, or sputtering; and.

FIG. 2 is a corresponding schematic representation of a process flow for an n-type crystalline silicon solar cell fabrication with deposition of the chemical onto the front and back surfaces of the PV device without Al₂O₃ deposited by PECVD, ALD, or sputtering.

### DESCRIPTION OF EMBODIMENTS

As disclosed above, the method of the present technology generally relates to liquid phase processable siloxane and metal-oxide polymer materials and their use in a solar cell manufacturing process. In particular, the present technology relates to materials which have suitable properties for use as passivation, hydrogenation, anti-reflection (front), and reflecting (back) dielectric coatings applied at the both sides of crystalline silicon solar cells. The present technology provides for the application of these materials in crystalline silicon solar cell device fabrication, and a method of producing such coating material compositions.

The passivating, hydrogenating, optical materials comprise typically either single or hybrid oxide compositions which can be deposited onto the silicon surface by means of an atmospheric liquid phase chemical coating method. Furthermore the coatings are applied as single or multiple layers on the silicon substrate using one or more different formulations or compositions to deposit each layer.

In an embodiment of the present technology, a method of passivating a silicon substrate, comprises the steps of providing a silicon substrate with or without a layer of vacuum coated Al₂O₃ of thickness ranging from 3 to 30nm by PECVD, sputter, or ALD at the front. Further, a passivating, hydrogenating, and anti-reflecting layer is introduced on the silicon substrate via liquid phase deposition. The passivating layer comprises oxygen, hydrogen and a metal or semimetal. The layer is capable of releasing the hydrogen.

An example of a suitable layer comprises a layer containing aluminium or silicon, or both, oxygen and hydrogen, optionally stacked with a layer comprising titanium oxide or tantalum oxide or titanium oxide and tantalum oxide hybrid.

At the back of the solar cell, there is a dielectric layer which can be similar to the passivating layer mentioned above. Typically the dielectric, hydrogen-releasing layer at the rear comprises silicon, oxygen, and hydrogen or optionally can by a hybrid oxide containing aluminium and/or titanium and/or tantalum. This dielectric layer formed at the rear of the silicon substrate is formed by liquid phase deposition.

Both of the passivating layers are capable of causing a reduction in the surface and bulk recombination velocity of the silicon substrate, while the rear side layer also is capable of improving internal reflection, especially for light at NIR range.

In a preferred embodiment, the surface recombination velocity is less than 100 cm/sec.

The silicon substrate is an n-type silicon solar cell substrate.

In preferred embodiments, the front passivating layer comprises aluminium, silicon, oxygen and hydrogen, or titanium, oxygen, and hydrogen, or tantalum, oxygen, and hydrogen, or silicon, oxygen, and hydrogen.

In a particularly preferred embodiment, the passivating layer is formed by polymerizing Si(OR¹)₄ and/or HSi(OR¹)₃, wherein R¹ is an alkyl group, preferably a linear or branched alkyl group having 1 to 8 carbon atoms, in particular a linear or branched alkyl group having 1 to 4 carbon atoms. Advantageously, the alkoxy group is methoxy or ethoxy.

In an embodiment, wherein the functional layer comprises a siloxane or metal oxide coating material, the molecular weight of that polymer or material is in the range of 400 to 150,000, preferably about 500 to 100,000, in particular about 750 to 50,000 g/mol.

The passivating layer is formed by polymerizing Ti(iOPr)₄, HSi(OR¹)₃ and TiCl₄ (for titanium oxide); by polymerizing Ta(iOPr)₅, HSi(OR¹)₃ and TaCl₅ (for tantalum oxide) or the passivating layer is formed by polymerizing HSi(OR¹)₃ and Al(iOPr)₃ (for aluminium oxide and silicon oxide hybrid).

The passivating layer, produced by any of the above embodiments, is capable of reducing the number of dangling bonds on the surface and bulk of the silicon substrate upon which the passivating layer is formed.

The anti-reflection layer is capable of increasing the absorption on a surface of the silicon substrate upon which the passivating layer is formed.

As discussed above, liquid phase deposition of the passivating layer is preferably performed at atmospheric pressure. The liquid phase coating is carried out by a method selected from the group of dip coating, slot coating, roller coating and spray coating and combinations thereof.

The silicon substrate, such as silicon wafer is part of a photovoltaic cell.

The photovoltaic cell is part of a photovoltaic panel/module.

The photovoltaic cell array is laminated with cover glass with thickness ranging from 1 mm to 4 mm.

The photovoltaic cell array is laminated with cover glass that is anti-reflection coated to further improve the efficiency of the photovoltaic cell.

The passivating and anti-reflection coatings or capping layers are preferably formed without a SiNx layer in between the coatings or capping layers, respectively.

However, it is also possible to vacuum depositing at least one SiNx layer in between the passivating and anti-reflection coatings or to vacuum depositing at least one SiNx layer in between the capping layers. In another embodiment, at least one SiNx layer is deposited by PECVD or sputtering.

In respect to the above discussion on hydrogenation and passivation, it should be pointed out that positively charged SiOx is well suitable for passivation for the emitter (sunny side) of p-type solar cell and for the back side of n-type solar cell due to the formation of accumulation layer through surface band-bending. Hydrogenation from SiOx further reduces both surface and bulk recombination velocity through chemical passivation of defects, which ties up the dangling bonds and reduces Dit (density of interface states).

Aluminium oxide is a highly negatively charged dielectric which provides excellent passivation for the back side of p-type solar cell or for the front side of n-type solar cell by forming an accumulation layer by surface field effect (band-bending).

With AlOx deposited on the back side of p-type solar cell, improved passivation is achieved compared to Al—BSF, while avoiding the parasitic shunting that would occur from using positively charged SiOx or SiNx.

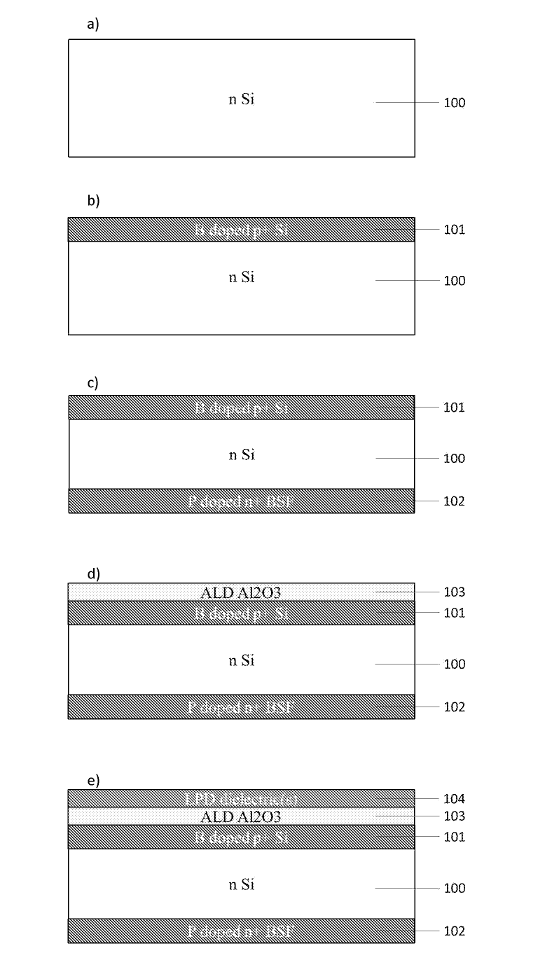

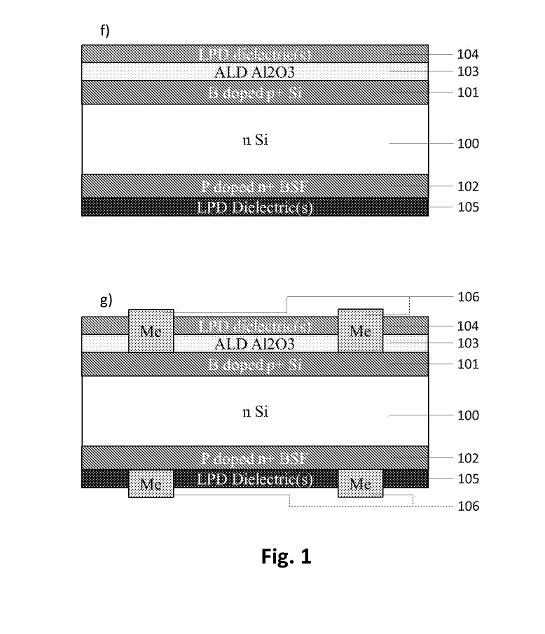

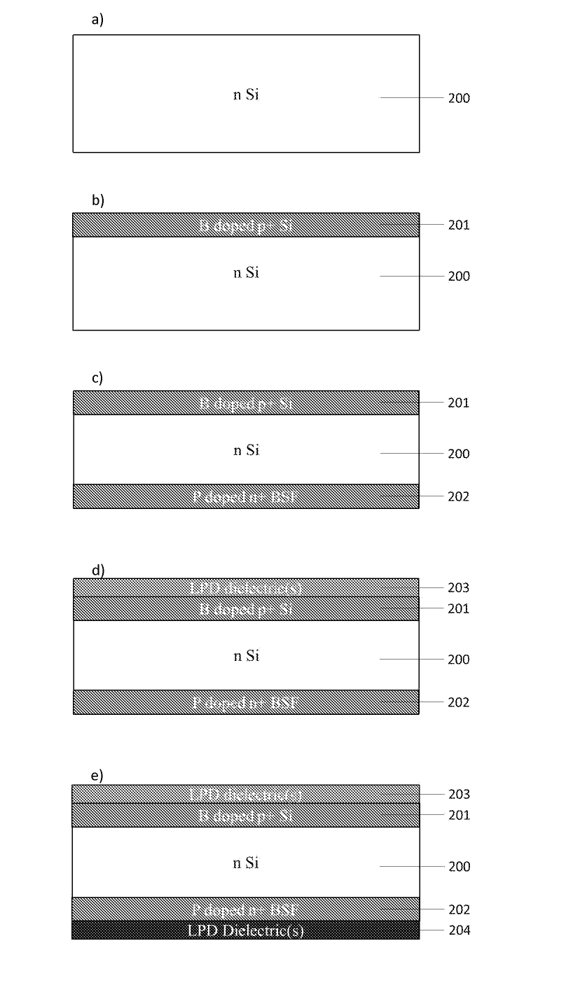

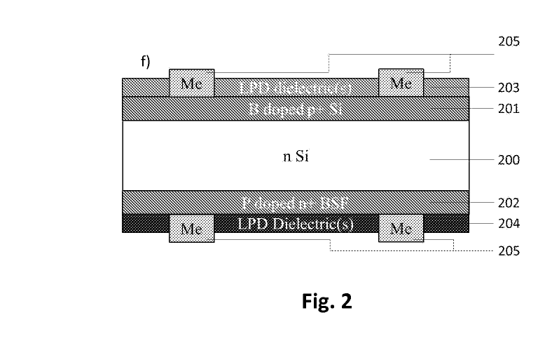

FIGS. 1 and 2 illustrate proposed steps to fabricate silicon wafer solar cell incorporating liquid phase deposited dielectrics at the front and back surfaces of the device.

Referring to FIG. 1a to 1g, there are cross sectional views provided showing the process flow for manufacturing an n-type crystalline silicon solar cell incorporating therein dielectric(s) in accordance with a preferred embodiment of the present invention in presence of vacuum deposited Al₂O₃ at the front.

The process for fabricating the silicon solar cell begins with a phosphorous doped n-type silicon substrate 100 which is saw-damage etched, textured and cleaned using wet chemicals. The substrate 100 undergoes either batch or inline doping and diffusion with boron bearing chemical source, which results into a positive boron doped region 101. The doped region 101 could be also achieved with other doping techniques, such as ion implantation. Back surface field (BSF) 102 is achieved with phosphorous diffusion either with batch inline methods. Borosilicate glass (BSG) and phosphorous silica glass (PSG) formed during diffusion are removed prior to the Al₂O₃ layer 103 deposited by PECVD, ALD, sputtering or other methods. The thickness of layer 103 varies from 3 to 30 nm.

Edge isolation of the solar cell can either be accomplished before Al₂O₃ deposition or after metallization at later stage. Dielectric 104 comprises a layer of liquid phase deposited hydrogenated aluminium oxide and silicon oxide which interfaces with silicon substrate, and a capping layer which is liquid phase deposited titanium oxide or tantalum oxide or similar. It is also possible that single dielectric layer is used without a separate capping layer.

A dielectric 105 comprising hydrogenated silicon oxide is liquid phase deposited at the rear side of solar cell. Higher open circuit voltage resulted from hydrogenation and improved short circuit current caused by increased internal reflection are expected. The dielectrics 104 and 105 can be deposited by using any wet chemical process methods including (but not limited to) spray coating, roller coating, ink-jet, dip coating, spin coating, slot coating.

The dielectrics 104 and 105 can be deposited as a full area film or alternatively can be deposited or processed to form a pattern on the silicon wafer surface. Typically, following this, contact 106 formation both at the front and back could be achieved by screen printing, inkjet printing, direct printing, physical vapor deposition (PVD), electroplating or others. Choices of the contact 106 can be aluminium (Al), silver (Ag), or copper (Cu). Referring to FIG. 1a to 1f, there are cross sectional views provided showing the process flow for manufacturing an n-type crystalline silicon solar cell incorporating therein dielectric(s) in accordance with a preferred embodiment of the present invention in absence of vacuumed deposited Al₂O₃ at the front.

The process for fabricating the silicon solar cell begins with a phosphorous doped n-type silicon substrate 200 which is saw-damage etched, textured and cleaned using wet chemicals. The substrate 200 undergoes either batch or inline doping and diffusion with boron bearing chemical source, which results into a positive boron doped region 201. The doped region 201 could be also achieved with other doping techniques, such as ion implantation. Back surface field (BSF) 202 is achieved with phosphorous diffusion either with batch inline methods. Borosilicate glass (BSG) and phosphorous silica glass (PSG) formed during diffusion are removed chemically. Edge isolation of the solar cell could either be accomplished before deposition of dielectric 203 or after metallization at later stage.

Dielectric 203 comprises a layer of liquid phase deposited hydrogenated aluminium oxide and silicon oxide which interfaces with silicon substrate, and a capping layer which is liquid phase deposited titanium oxide or tantalum oxide. It is also possible that single dielectric layer is used without a separate capping layer. Dielectric 204 comprising hydrogenated silicon oxide is liquid phase deposited at the rear side of solar cell. Higher open circuit voltage resulted from hydrogenation and improved short circuit current caused by increased internal reflection are expected. The dielectrics 203 and 204 can be deposited by using any wet chemical process methods including (but not limited to) spray coating, roller coating, ink-jet, dip coating, spin coating, slot coating. The dielectrics 203 and 204 can be deposited as a full area film or alternatively can be deposited or processed to form a pattern on the silicon wafer surface. Following this, contact 205 formation both at the front and back could be achieved by screen printing, inkjet printing, direct printing, physical vapor deposition (PVD), electrical plating or others. Choices of the contact 205 can be aluminium (Al), silver (Ag), or copper (Cu).

Table 1 shows two ways of manufacturing n-type screen printed cell with LPD passivating dielectrics compared to that using ALD Al₂O₃ capped with PECVD SiNx. Float zone (FZ) phosphorous doped n-type silicon with resistivity of 3 Ω·cm is the starting material for the device. The solar cell process comprises an alkaline texture at the front and a polished surface at the back. At the front side, a p+ emitter with a sheet resistance of 70 Ω/□ was diffused from a boron tribromide (BBr3) source. The BSF at the back is formed in another diffusion step by diffusing phosphorous using POCl₃ source to achieve a sheet resistance of 40 Ω/□. The passivation of the front boron emitter is achieved either by LPD AlOx:SiOx capped with LPD TiOx or ALD Al₂O₃ capped with LPD TiOx. For the structure with pure LPD solution at the front, the thickness and RI of AlOx:SiOx are 50 nm and 1.50 respectively.

The thickness and RI of TiOx are 30 nm and 2.5 respectively. In the case of front passivation using ALD Al2O3 capped with LPD TiOx, the thickness and RI of ALD Al₂O₃ are 10 nm and 1.60 respectively. The LPD TiOx capping layer on the top of ALD Al₂O₃ is of thickness at 70 nm and RI at 2.10. Both structures are passivated by liquid phase deposited hydrogenated SiOx at the back. The thickness and RI of the LPD SiOx are 100 nm and 1.40 respectively.

Table 1 lists process parameters for screen printed n-type solar cell using LPD passivating dielectrics compared to ALD Al₂O₃ at the front

TABLE 1

| | ALD Al₂O₃ + PECVD | LPD AlOx:SiOx + LPD | ALD Al₂O₃ + LPD |
|---|---|---|---|
| | SiNx cap | TiOx | TiOx |
| | n-type (100) FZ 5 | n-type (100) FZ 5 | n-type (100) FZ 5 |
| Substrate material | Ω · cm | Ω · cm | Ω · cm |
| Wafer thickness, μm | 200 | 200 | 200 |
| p + Emitter Rsh, Ω / [symbol] | 70 | 70 | 70 |
| n + BSF Rsh, Ω/ [symbol] | 40 | 40 | 40 |
| ALD Al₂O₃ thickness | 10 | NA | 10 |
| ALD Al₂O₃ RI @ 633 | 1.60 | NA | 1.60 |
| nm | | | |
| SiNx ARC thickness, | 70 | NA | NA |
| nm | | | |
| SiNx ARC RI @ | 2.00 | NA | NA |
| 633 nm | | | |
| LPD AlOx:SiOx | NA | 50 | NA |
| LPD AlOx:SiOx RI @ | NA | 1.50 | NA |
| 633 nm | | | |
| LPD TiOx thickness, | NA | 30 | 70 |
| nm | | | |
| LPD TiOx RI @ | NA | 2.50 | 2.10 |
| 633 nm | | | |
| LPD SiOx:H | NA | 100 | 100 |
| thickness, nm (Back) | | | |
| LPD SiOx:H RI @ 633 | NA | 1.40 | 1.40 |
| nm | | | |
| PECVD SiNx (at the | 2.00 | NA | NA |
| back) RI @ 633 nm | | | |
| LPD SiOx (at the | NA | 100 | 100 |
| back) thickness, nm | | | |
| LPD SiOx (at the | NA | 1.4 | 1.4 |
| back) RI @ 633 nm | | | |
| Joe, fA/cm2 | 50 | <75 | NA |
| SRV at the back, | <10 | <50 | <50 |
| cm/s | | | |

In a preferred embodiment, the functional layers, which also can be called hydrogen releasing and passivating layers, are formed from siloxane/silane polymers, hybrid organic-inorganic polymers or carbosilane polymers. The polymers can be produced from various intermediates, precursors and monomers.

Furthermore, the above mentioned polymers contain at least one monomer, precursor or polymer that has a group or a substituent or a part of the molecules that has a hydrogen atom, and which capable of releasing that hydrogen atom, in particular in subsequent processing steps of the functional layer in solar cell manufacturing process. The hydrogen releasing monomer can be a silane precursor, for example trimethoxysilane, triethoxysilane (generally any trialkoxysilane, wherein alkoxy has 1 to 8 carbon atoms), a trihalosilane, such as trichlorosilane, or similar silanes, in particular of the kind which contain at least one hydrogen after hydrolysis and condensation polymerization. It can be used as monomeric additive in the coating material or hydrolyzed and condensated as part of the material backbone matrix. Also other silane types can be used as hydrogen releasing entities, including bi-silanes, and carbosilanes which contain hydrogen moiety. Generally, it is required that the hydrogen releasing group or substituent or part of the molecule contains a hydrogen which is bonded to a metal or a semimetal atom, preferably to a metal or a semimetal atom in the polymeric structure forming the layer. The hydrogen can also be bonded to a carbon atom, provided that the hydrogen is released upon treatment of the functional layers.

Hybrid organic-inorganic polymers can be synthesized by using silane or metal (or semimetal) oxide monomers or, and in particular, combinations of silane and metal oxide monomers as starting materials. Furthermore, the final coating chemical (precursor, monomer, polymer, intermediate, catalyst or solvent) has hydrogen moiety in the composition and that hydrogen being able to be released then during the solar cell manufacturing process to provide hydrogenation and passivation qualities. The polymers and intermediates have a siloxane backbone comprising repeating units of —Si—C—Si—O and/or Si—O— and/or —Si —C—Si—C. Generally, in the formula (Si—O—)ₙ and in the formula (—Si—C—Si—O—)ₙ and in the formulas (—Si—C—)ₙ the symbol n stands for an integer 4 to 10,000, in particular about 10 to 5000. In the case of using hybrid silane and metal oxide monomers the polymer and intermediates have a backbone comprising repeating units —Si—O—Me-O (where Me indicates metal atom such as Ti, Ta, Al or similar). The hybrid silane—metal oxide backbone can be also different to this.

Hybrid organic-inorganic polycondensates can be synthesized by using metal alkoxides and/or metal salts as metal precursors. Metal precursors are first hydrolysed, and metal alkoxides are typically used as the main source for the metal precursors. Due to the different hydrolysis rate, the metal alkoxides must be first hydrolysed and then chelated or otherwise inactivated in order to prevent self-condensation into monocondensate Me-O-Me precipitates. In the presence of water, this can be controlled by controlling the pH, which controls the complex ions formation and their coordination. For example, aluminum can typically form four-fold coordinated complex-ions in alkaline conditions and six-fold coordinated complex-ions in acidic conditions. By using metal salts as co-precursors, such as nitrates, chlorides, sulfates, and so on, their counter-ions and their hydrolysable metal complex-ions can conduct the formation of different coordination states into the final metal precursor hydrolysate.

Once a hydrolysed metal precursor is achieved, the next step is to introduce the silica species into the chelated or inactivated metal precursor solution. Silica sources are first dissolved and hydrolysed, at least partially, either directly in the metal precursor solution or before its introduction into the metal precursor solution. During or after the introduction, the partially or fully hydrolysed silica species are then let to react with the metal hydrolysate to form a polycondensate. The reaction can be catalyzed by altering the temperature, concentration, temperature, and so on, and it typically occurs at higher temperatures than room temperature. Due to the nature of metal complex-ions in general, it is often common that the polycondensates resembles rather a nanoparticulate structure than a linear polymer, which therefore has to be further electrochemically or colloidally stabilized to sustain its nanosized measures in the coating solution. During processing, the solution further forms a coating that will have its final degree of condensation after heat-treatment, where the major part of rest of the hydrolyzed groups are removed.

Again for example triethoxysilane (or another one of the above mentioned monomers) can be used as the hydrogen releasing moiety in the material. The Triethoxysilane is hydrolyzed and condensation polymerized example with the metal (semimetal) alkokside to results in final product. It is also possible to make the synthesis from halogenide based precursor and other types as well.

In the polymeric structures disclosed above, there is preferably a releasable hydrogen directly bonded to a metal or semimetal atom.

There can be up to one releasable hydrogen attached to each repeating metal or semimetal atom of the backbone.

The precursor molecules of the siloxane and/or metal (semimetal) oxide polymers can be penta-, tetra-, tri-, di-, or mono-functional molecules. A penta-functional molecule has five hydrolysable groups; tetra-functional molecule has four hydrolysable groups; a tri-functional molecule has three hydrolysable groups; a di-functional molecule has two; and mono-functional molecule has one. The precursor molecules, i.e. silane and metal oxide monomers can be have organic functionalities. The precursor molecules can be also bi-silanes and especially in case of some metal oxide or hybrid metal oxide it is possible to use some stabilizing agents in the composition in addition to other additives and catalyst. The molecular weight range for the siloxane and/or metal oxide coating material is in range of 400 to 150,000, preferably about 500 to 100,000, in particular about 750 to 50,000 g/mol.

A wet chemical coating is prepared from the coating solution by any typical liquid application (coating) processes, preferably with spin-on, dip, spray, ink-jet, roll-to-roll, gravure, flexo-graphic, curtain, drip, roller, screen printing coating methods, extrusion coating and slit coating, but are not limited to these.

According to one embodiment, the process according to the invention comprises hydrolyzing and polymerizing a monomers according to either or both of formulas I and II:

R¹ₐSiX₄₋ₐ I

and

R²_{b}SiX_{4-b} II

wherein R¹ and R² are independently selected from the group consisting of hydrogen, linear and branched alkyl and cycloalkyl, alkenyl, alkynyl, (alk)acrylate, epoxy, allyl, vinyl and alkoxy and aryl having 1 to 6 rings; each X represents independently halogen, a hydrolysable group or a hydrocarbon residue; and
a and b is an integer 1 to 3.

Further, in combination with monomers of formula I or II or as such at least one monomer corresponding to Formula III can be employed:

R³_{c}SiX_{4-c} III

wherein R³ stands for hydrogen, alkyl or cycloalkyl which optionally carries one or several substituents, or alkoxy;
each X represents independently halogen, a hydrolysable group or a hydrocarbon residue having the same meaning as above; and
c is an integer 1 to 3.

In any of the formulas above, the hydrolysable group is in particular an alkoxy group (cf. formula IV).

As discussed above, in the present invention organosiloxane polymers are produced using tri- or tetraalkoxysilane. The alkoxy groups of the silane can be identical or different and preferably selected from the group of radicals having the formula

—O—R⁴ IV

wherein R⁴ stands for a linear or branched alkyl group having 1 to 10, preferably 1 to 6 carbon atoms, and optionally exhibiting one or two substitutents selected from the group of halogen, hydroxyl, vinyl, epoxy and allyl.

The above precursor molecules are condensation polymerized to achieve the final siloxane polymer composition. Generally, in case of tri-, di- and mono-functional molecules, the other functional groups (depending on the number of hydrolysable group number) of the precursor molecules can be organic functionalities such as linear, aryl, cyclic, aliphatic groups. These organic groups can also contain reactive functional groups e.g. amine, epoxy, acryloxy, allyl or vinyl groups. These reactive organic groups can optionally react during the thermal or radiation initiated curing step. Thermal and radiation sensitive initiators can be used to achieve specific curing properties from the material composition.

According to a preferred embodiment, when using the above monomers, at least one of the monomers used for hydrolysation and condensation is selected from monomers having formulas I or II, wherein at least one substituent is a group capable of providing the hydrogenation and passivation characteristics for the coated film. For preparing the prepolymer, the molar portion of units derived from such monomers (or the molar portion of monomers containing the active group calculated from the total amount of monomers) is about 0.1 to 100%, preferably about 20%-100%, in particular about 30% to 100%. In some cases, the group will be present in a concentration of about 30% based on the molar portion of monomers.

In the above polymers, the relation (molar ratio) between monomers providing releasable hydrogens in the polymeric material and monomers which do not contain or provide such hydrogens is preferably 1:10, in particular 5:10, preferably 10:10-1000:10. It is possible even to employ only monomers leaving a releasable hydrogen for the production of the polymer.

The carbosilane polymer can be synthesized for example by using Grignard coupling of chloromethyltrichlorosilane in the presence THF followed by reduction with lithium aluminum hydride. A general reaction route is given below. The end product contains two hydrogens bonded to the silicon atom which are capable being released during the processing of the silicon solar cell. The final product is dissolved in a processing solvent and can be processed as is using the liquid phase deposition. The final product can be used also as dopant, additive or reacted with silane or metal (or semimetal) backbone to results as coating material.

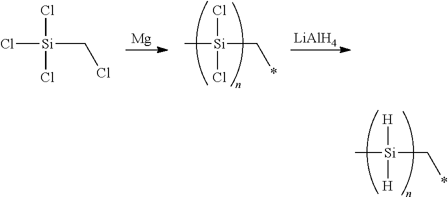

According to a preferred embodiment, when using the above monomers, at least one of the monomers used for hydrolysation and condensation is selected from monomers having formulas I or II, wherein at least one substituent is a group capable of providing the hydrogenation and passivation characteristics for the coated film. For preparing the prepolymer, the molar portion of units derived from such monomers (or the molar portion of monomers containing the active group calculated from the total amount of monomers) is about 0.1 to 100%, preferably about 20% to 100%, in particular about 30% to 100%. In some cases, the group will be present in a concentration of about 30% based on the molar portion of monomers.

According to one embodiment, at least 50 mol-% of the monomers are being selected from the group of tetraethoxysilane, triethoxysilane, tetramethoxysilane, trimethoxysilane, tetrachlorosilane, trichlorosilane, and mixtures thereof.

According to one embodiment, the solution coating polymer composition comprises a siloxane polymer, hybrid silane metal oxide polymer or carbosilane polymer in a solvent phase, wherein the partially cross-linked prepolymer has a siloxane or hybrid silane metal oxide or carbosilane backbone formed by repeating units and having a molecular weight in the range of from about 1,000 to about 15,000 g/mol, for example 2,000 to 10,000 g/mol. In addition, the (pre)polymer backbone exhibits 1 to 100 releasable hydrogen per 100 repeating units.

According to another embodiment, the siloxane composition comprises a siloxane polymer, hybrid silane metal oxide polymer or carbosilane polymer in a solvent phase, wherein
the partially cross-linked prepolymer has a siloxane backbone formed by repeating —Si—O— units and having a molecular weight in the range of from about 4,000 to about 10,000 g/mol, the siloxane backbone exhibiting hydroxyl groups in an amount of about 5 to 70% of the —Si—O— units and further exhibiting epoxy groups in an amount of 1 to 15 mol %, calculated from the amount of repeating units; and the composition further comprises 0.1-3%, based on the weight of the solid matter, at least one cationic photo reactive compound.

The synthesis of the siloxane polymer is carried out in two steps. In the first synthesis step, in the following also called the hydrolysis step, the precursor molecules are hydrolyzed in presence typically of water and a catalyst, such as hydrochloric acid or nitric acid or another mineral or organic acid or a base, and in the second step, the polymerization step, the molecular weight of the material is increased by condensation polymerization or other crosslinking depending on what precursors are chosen to the synthesis. The water used in the hydrolysis step has typically a pH of less than 7, preferably less than 6, in particular less than 5.

It may be preferable in some cases to carry out the condensation polymerization in the presence of a suitable catalyst. In this step the molecular weight of the prepolymer is increased to facilitate suitable properties of the material and film deposition and processing.

The siloxane polymer synthesis, including the hydrolysis, the condensation and the cross-linking reactions, can be carried out using an inert solvent or inert solvent mixture, such as acetone or PGMEA, “non-inert solvent”, such as alcohols, or without a solvent. The used solvent affects the final siloxane polymer composition. The reaction can be carried out in basic, neutral or acidic conditions in the presence of a catalyst. The hydrolysis of the precursors may be done in the presence of water (excess of water, stoichiometric amount of water or sub-stoichiometric amount of water). Heat may be applied during the reaction and refluxing can be used during the reaction.

Typically before the further condensation the excess of water is removed from the material and at this stage it is possible to make a solvent exchange to another synthesis solvent if desired. This other synthesis solvent may function as the final or one of the final processing solvents of the siloxane polymer. The residual water and alcohols and other by-products may be removed after the further condensation step is finalized. Additional processing solvent(s) may be added during the formulation step to form the final processing solvent combination. Additives such as thermal initiators, radiation sensitive initiators, surfactants and other additives may be added prior to final filtration of the siloxane polymer. After the formulation of the composition, the polymer is ready for processing.

Suitable solvents for the synthesis are, for example, acetone, tetrahydrofuran (THF), toluene, 1-propanol, 2-propanol, methanol, ethanol, propylene glycol monomethyl ether, propylene glycol propyl ether, methyl-tert-butylether (MTBE), propylene glycol monomethylether acetate (PGMEA), propylene glycol monomethylether PGME and propylene glycol propyl ether (PnP), PNB, IPA, MIBK, Glycol Ethers (Oxitols, Proxitols), Butyl Acetates, MEK Acetate, or mixtures of these solvents or other suitable solvents.

After synthesis, the material is diluted using a proper solvent or solvent combination to give a solid content and coating solution properties which with the selected film deposition method will yield the pre-selected film thickness. Suitable solvents for the formulation are example 1-propanol, 2-propanol, ethanol, propylene glycol monomethyl ether, propylene glycol propyl ether (PNP), PNB (propandiol-monobutyl ether), methyl-tert-butylether (MTBE), propylene glycol monomethylether acetate (PGMEA), propylene glycol monomethylether PGME and PNB, IPA, MIBK, Glycol Ethers (Oxitols, Proxitols), Butyl Acetates, MEK Acetate, or mixtures of these solvents or other suitable solvents.

The final coating film thickness has to be optimized according for each device and structure fabrication process. In addition to using different solvents it is also possible to use surfactants and other additives to improve the coating film quality, wetting and conformality on the silicon cell.

Optionally, an initiator or catalyst compound is added to the siloxane composition after synthesis. The initiator, which can be similar to the one added during polymerization, is used for creating a species that can initiate the polymerization of the “active” functional group in the UV curing step. Thus, in case of an epoxy group, cationic or anionic initiators can be used. In case of a group with double bonds as “active” functional group in the synthesized material, radical initiators can be employed. Also thermal initiators (working according to the radical, cationic or anionic mechanism) can be used to facilitate the cross-linking of the “active” functional groups. The choice of a proper combination of the photoinitiators also depends on the used exposure source (wavelength). Also photoacid generators and thermal acid generators can be used to facilitate improved film curing. The concentration of the photo or thermally reactive compound in the composition is generally about 0.1 to 10%, preferably about 0.5 to 5%, calculated from the mass of the siloxane polymer.

Film thicknesses may range e.g. from 1 nm to 500 nm. Various methods of producing thin films are described in U.S. Pat. No. 7,094,709, the contents of which are herewith incorporated by reference.

A film produced according to the invention typically has an index of refraction in the range from 1.2 to 2.4 at a wavelength of 633 nm.

The composition as described above may comprise solid nanoparticles in an amount between 1 and 50 wt-% of the composition. The nanoparticles are in particular selected from the group of light scattering pigments and inorganic phosphors or similar. By means of the invention, materials are provided which are suitable for producing films and patterned structures on silicon cells. The patterning of the thermally and/or irradiation sensitive material compositions can be performed via direct lithographic patterning, laser patterning and exposure, conventional lithographic masking and etching procedure, imprinting, ink-jet, screen-printing and embossing, but are not limited to these.

The compositions can be used for making layers which are cured at relatively low processing temperatures, e.g. at a temperature of max 375° C. or even at temperature of 100° C. and in the range between these limits.

However the coating layer formed from the material compositions can also be cured at higher temperatures, i.e. at temperatures over 375° C. and up to 900° C., or even up to 1100° C., making it possible for the material films or structures to be cured at a high temperature curing, such as can be combined with a subsequent high temperature deposition and firing steps.

In the following, there is presented a number of non-limiting working examples giving further details of the preparation of the above-discussed siloxane polymer, hybrid silane-metal oxide polymer and carbosilane coating compositions, suitable for forming passivating and hydrogen-releasing layers on silicon substrates in photovoltaic devices. These materials can be applied as discussed above in connection with the drawings.

### EXAMPLE 1

Tetraethyl orthosilicate (28.00 g) and Triethoxysilane (42.00 g) and solvent (ethanol) were weighted into the 1 L flask and stirred for 30 minutes. 0.01 M HCl (2× equivalent) was added. Material was refluxed for one hour. Solvent exchange was done to propylene glycol propyl ether (PnP). A further condensation polymerization was carried out in presence of catalyst (triethylamine). After this trimethylmethoxysilane (0.02 g) was added and further solvent exchange done to propylene glycol propyl ether (PnP). Material was diluted to process formulation and filtrated with 0.1 μm filter to obtain process ready solution.

### EXAMPLE 2

Tetraethyl orthosilicate (14.00 g) and Triethoxysilane (60.00 g) and solvent (2-propanol) were weighted into the 1 L flask and stirred for 30 minutes. 0.01 M HCl (0.6 equivalent) was added. Material was refluxed for one hour. Solvent exchange was done to propandiol-monobutyl ether (PNB). A further condensation polymerization was carried out in presence of catalyst (triethylamine). After this trimethylmethoxysilane (0.021 g) was added and further solvent exchange done to propylene glycol propyl ether (PnP). Material was diluted to process formulation and filtrated with 0.1 μm filter to obtain process ready solution.

### EXAMPLE 3

Methyl-trimethoxysilane (15.00 g), 3-Glycidoxypropyl-trimethoxysilane (9.00 g) and Triethoxysilane (75.00 g) and solvent (2-propanol) were weighted into the 1 L flask and stirred for 30 minutes. 0.01 M HCl (1 equivalent) was added. Material was refluxed for one hour. Solvent exchange was done to propylene glycol propyl ether (PnP). A further condensation polymerization was carried out in presence of catalyst (triethylamine). After this trimethylethoxysilane (0.025 g) was added and further solvent exchange done to propylene glycol propyl ether (PnP). Material was diluted to process formulation and filtrated with 0.1 μm filter to obtain process ready solution.

### EXAMPLE 4

Tetraethyl orthosilicate (5.00 g) and Triethoxysilane (82.00 g) and solvent (2-propanol) were weighted into the 1 L flask and stirred for 30 minutes. 0.01 M HCl (1 equivalent) was added. Material was refluxed for one hour. Solvent exchange was done to propylene glycol propyl ether (PnP). A further condensation polymerization was carried out in presence of catalyst (triethylamine). After this trimethylethoxysilane (0.025 g) was added and further solvent exchange done to propylene glycol propyl ether (PnP). Material was diluted to process formulation and filtrated with 0.1 μm filter to obtain process ready solution.

### EXAMPLE 5

Triethoxysilane (98.00 g) and solvent (2-propanol) were weighted into the 1 L flask and stirred for 30 minutes. 0.01 M HCl (0.6 equivalent) was added. Material was refluxed for one hour. Solvent exchange was done to propylene glycol propyl ether (PnP). A further condensation polymerization was carried out in presence of catalyst (triethylamine). After this trimethylchlorosilane (0.02 g) was added and further solvent exchange done to propylene glycol propyl ether (PnP). Material was diluted to process formulation and filtrated with 0.1 μm filter to obtain process ready solution.

### EXAMPLE 6

Aluminium nitrate-nonahydrate (180 g) in water solution was mixed with Aluminium isopropoxide (80 g). After that triethoxysilane (15 g) was added. Solution was refluxed for 4 hours. 1-propanol was added as processing solvent and filtrated with 0.1 μm filter to obtain process ready solution.

### EXAMPLE 7

Aluminium nitrate-nonahydrate (180 g) in water solution was mixed with Aluminium isopropoxide (40 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 8

Aluminium nitrate-nonahydrate (180 g) in water solution was mixed with Aluminium isopropoxide (20 g) and Titanium isopropoxide (25 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 9

Aluminium nitrate-nonahydrate (180 g) in water solution was mixed with Titanium (IV) isopropoxide (38 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 10

Aluminium nitrate-nonahydrate (180 g) in water solution was mixed with Aluminium isopropoxide (20 g) and Tantalum ethoxide (22 g). After that triethoxysilane (15 g) was added. Solution was refluxed for 4 hours. Solvent exchanged was performed to 1-propanol. The solution was filtrated with 0.1 μm filter to obtain process ready solution.

### EXAMPLE 11

Aluminium nitrate-nonahydrate (180 g) in water solution was mixed with Aluminium isopropoxide (35 g). After that tetraethyl orthosilicate (5 g) and triethoxysilane (14 g) was added. Solution was refluxed for 4 hours. Solvent exchanged was performed to 1-propanol. The solution was filtrated with 0.04 μm filter to obtain process ready solution.

### EXAMPLE 12

20 g of Aluminium s-butoxide and 200 g of PGEE were mixed for 30 min. 15.58 g of Ethyl Acetoacetate was added and followed by addition of triethoxysilane (11 g) was added and mixed. Mixture of H₂O and PGEE (8 g and 40 g) was added. The solution was filtrated with 0.1 μm filter to obtain process ready solution.

### EXAMPLE 13

20 g of AlCl₃ was dissolved to EtOH (200 g) and TiCl₄ (10 g)+Ti(iOPr)₄ (14 g) was dissolved to 200 g of EtOH. Dissolved solutions were combined. Solution was stirred for 60 min at RT. Triethoxysilane (15 g) was added and solution was stirred at RT for 60 min. EtOH was distilled using membrane pump. 220 g of 2-isopropoxyethanol was added to the material flask. Solution was cooled down and filtrated. Solution was formulated to the final processing solvent 1-butanol and was filtrated with 0.1 μm filter to obtain process ready solution.

### EXAMPLE 14

Mg (8 g) was charged in reactor flask and the atmosphere was changed from air to N₂. Dry THF (175 ml) was added to Mg and Cl₃SiCH₂Cl (35 mL) was added at RT. Solution was refluxed for 4 hours. The reaction mixture was washed with dry THF and LiAlH₄ was added (4.0 grams). The solution was refluxed for 2 hours. The solvent was changed to pentane and extracted (300-400 mL). The solution was filtrated and solvent exchange was made to propylene glycol propyl ether (PnP). Material was diluted to process formulation and filtrated with 0.1 μm filter to obtain process ready solution.

### EXAMPLE 15

Mg (12 g) was charged in a reactor flask and the atmosphere was changed from air to N₂. Dry THF was added to Mg and Cl₃SiCH₂Cl (35 mL) was added at RT. CuCN was added to the reaction mixture. Solution was refluxed for 4 hours. The reaction mixture was washed with dry THF and LiAlH₄ was added (4.0 grams). The solution was refluxed for 2 hours. The solvent was changed to pentane and extracted (300-400 mL). The solution was filtrated and solvent exchange was made to propylene glycol propyl ether (PnP). The material was diluted to process formulation and filtrated with 0.1 μm filter to obtain process ready solution.

### EXAMPLE 16

Basic recipe: Place 704 grams of Titanium (IV) isopropoxide to reactor flask. Add 470 grams of titanium tetrachloride to reactor. Add 5760 ml of methanol to the reactor and stir the reaction solution for 2 hours.

MeOH was distilled using membrane pump, distillation apparatus and oil bath. 5872 grams of 2-isopropoxyethanol was added to the material flask. The solution was cooled down to 6° C. 1013 g of TEA was added the way that the material solution temperature was kept between −6° C. and +6° C. during TEA addition. The solution was filtrated using a Buchner funnel. The solution was cooled down in the reactor over night. Finally the solution was filtrated using a filter paper. The solution was formulated to the final processing solvent IPA and was ready for processing after final filtration.

### EXAMPLE 17

20 g of AlCl₃ was dissolved to 200 g of EtOH and TiCl₄(9,48 g)+Ti(iOPr)₄ (14.21 g) was dissolved to 200 g of EtOH. Dissolved solutions were combined. Solution was stirred for 60 min at RT. EtOH was distilled using membrane pump, distillation apparatus and oil bath. 220 g of 2-isopropoxyethanol was added to the material flask. The solution was cooled down to 6° C. 101.18 g of TEA was added in 10 min. Material solution temperature was kept between 6° C. and +6° C. during TEA addition. The solution was filtrated using a Buchner funnel. The solution was placed to the freezer over night. Finally the solution was filtrated using a filter paper. The solution was formulated to the final processing solvent EtOH and was ready for processing after final filtration.

### EXAMPLE 18

20 g of Aluminium s-butoxide and 200 g of PGEE were weighted to a round bottom flask and stirred at room temperature for 30 min. 15.58 g of Ethyl Acetoacetate was added drop-wise to the solution and stirring at room temperature was continued further 1 h. Mixture of H20PGEE (8 g/40 g) was added to the clear solution dropwise by Pasteur pipette and solution was stirred at room temperature overnight. The solid content of the material is 4.49 w-%

### EXAMPLE 19

To a round bottom flask containing 182.7 of ANN-DI water, 42.27 g of Aluminum-isopropoxide (AlP) power was added during 40 min under strong stirring. After AlP addition, 19.18 g of TEOS was added drop-wise during 30 min. The clear solution was stirred over a night at room temperature. Solution was heated up to 60° C. using an oil bath and condenser and stirred at 60° C. for 4 hours. After 4 hours clear solution was further stirred at room temperature for over a night.

Solvent exchange was carried out from DI water to 1-propanol using a rotary evaporator with three 1-propanol addition steps (Water bath temperature 60° C.). The total amount of added 1-propanol was 136 g. Total amount of removed solution was 195 g. After solvent exchange solid content of the solution was 16.85 w-%.

1. A method of modifying a silicon substrate which is intended for use in a photovoltaic device, comprising the steps of
providing an n-type silicon substrate having a bulk and exhibiting a front surface and a rear surface; and
forming by liquid phase application dielectric layers on said front and rear surfaces;
wherein the dielectric layer formed at the rear surface is capable of acting as a reflector to enhance reflection of light into the bulk of the silicon substrate, and
wherein the dielectric layer formed at the front comprises oxygen, hydrogen and at least one metal or semimetal and is capable of releasing hydrogen into the bulk as well as onto the surfaces of the silicon substrate in order to provide hydrogenation and passivation.

2. The method according to claim 1, wherein the dielectric layers have thicknesses ranging from 5 to 250 nm.

3. The method according to claim 1, wherein the layer formed on the front is capable of reducing surface and bulk recombination, and to improve light absorption, when the silicon substrate is used in a photovoltaic device.

4. The method according to claim 1, further comprising forming at the front a layer of vacuum coated Al₂O₃ having a thickness in the range from 1 to 50 nm, said layer preferably being formed by plasma-enhanced CVD, by sputtering, or by atomic layer deposition.

5. The method of claim 4, wherein the Al₂O₃ layer is formed on top of the hydrogen-releasing layer, on the opposite side to the substrate.

6. The method according to claim 1, comprising additionally forming, as part of a stack of layers on the front of the silicon substrate, at least one layer of titanium oxide or tantalum oxide or of a titanium oxide and tantalum oxide hybrid material.

7. The method according to claim 6, wherein said titanium or tantalum oxide or hybrid material is a capping layer formed on top of the hydrogen-releasing layer or on top of the Al₂O₃, layer, on the opposite side to the substrate.

8. The method according to claim 1, wherein the dielectric layer formed at the rear surface is capable of acting as a reflector to enhance reflection of light in the NIR range into the bulk of the silicon substrate.

9. The method according to claim 1, wherein the surface recombination velocity of the modified silicon substrate is less than 100 cm/sec.

10. The method according to claim 1, wherein the hydrogen-releasing layer on the front side comprises
aluminium, silicon, oxygen and hydrogen, or
titanium, oxygen and hydrogen, or
tantalum, oxygen and hydrogen.

11. The method according to claim 1, further comprising forming by liquid phase application on said rear surface a dielectric layer comprising oxygen, hydrogen and at least one metal or semimetal, capable of releasing hydrogen into the bulk as well as onto the surfaces of the silicon substrate in order to provide hydrogenation and passivation.

12. The method according to claim 11, wherein the hydrogen-releasing dielectric layer on the rear side comprises silicon, oxygen and hydrogen.

13. The method according to claim 1, wherein the hydrogen-releasing layer(s) is (are) capable of reducing the number of dangling bonds on the surface and in the bulk of the silicon substrate upon which the passivating layer is formed.

14. The method according to claim 1, wherein the hydrogen-releasing layer is formed by polymerizing Si(OR¹)4 and/or HSi(OR¹)3, wherein R¹ is an alkyl group.

15. The method according to claim 14, wherein the alkoxy group is methoxy or ethoxy.

16. The method according to claim 1, wherein the hydrogen-releasing layer is formed by polymerizing: Si(OR¹)₄ and/or HSKOR¹)₃ (for hydrogenated silicon oxide); Ti(iOPr)₄, HSi(OR¹) and TiCl₄ (for titanium oxide); Ti(iOPr)₅, HSi(OR¹)₃ and TaCl₅ (for tantalum oxide); or HSi(OR¹)₃ and Al(iOPr)₃ (for aluminium oxide and silicon oxide hybrid).

17. (canceled)

18. (canceled)

19. (canceled)

20. The method according to claim 1, wherein liquid phase deposition of the hydrogen-releasing layer is performed at atmospheric pressure.

21. The method according to claim 1, wherein liquid phase coating is carried out by dip coating, slot coating, roller coating and spray coating.

22. A modified silicon substrate obtained by a method comprising the steps of:
providing an n-type silicon substrate having a bulk and exhibiting a front surface and a rear surface; and
forming by liquid phase application dielectric layers on said front and rear surfaces;
wherein the dielectric layer formed at the rear surface is capable of acting as a reflector enhance reflection of light into the bulk of the silicon substrate, and
wherein the dielectric layer formed at the front comprises oxygen, hydrogen and at least one metal or semimetal and is capable of releasing hydrogen into the bulk as well as onto the surfaces of the silicon substrate in order to provide hydrogenation and passivation.

23. A photovoltaic device comprising a modified silicon substrate obtained by a method comprising the steps of:
providing an n-type silicon substrate having a bulk and exhibiting a front surface and a rear surface; and
forming by liquid phase application dielectric layers on said front and rear surfaces;
wherein the dielectric layer formed at the rear surface is capable of acting as a reflector enhance reflection of light into the bulk of the silicon substrate, and
wherein the dielectric layer formed at the front comprises oxygen, hydrogen and at least one metal or semimetal and is capable of releasing hydrogen into the bulk as well as onto the surfaces of the silicon substrate in order to provide hydrogenation and passivation.
